(19) United States
(12) Patent Application Publication
(10) Pub. No.: US 2026/0304755 A1
(43) Pub. Date: Oct. 1, 2026

(54) SEMICONDUCTOR DEVICE, MEMORY AND MANUFACTURING METHOD THEREFOR, AND ELECTRONIC DEVICE

(71) Applicant: BEIJING SUPERSTRING ACADEMY OF MEMORY TECHNOLOGY, Beijing (CN)

(72) Inventors: Zhengyong ZHU, Beijing (CN); Bok Moon KANG, Beijing (CN); Chao ZHAO, Beijing (CN)

(21) Appl. No.: 19/474,908

(22) PCT Filed: Oct. 20, 2023
(86) PCT No.: PCT/CN2023/125603

§ 371 Date: Oct. 13, 2025

(30) Foreign Application Priority Data
Apr. 20, 2023 (CN) 202310428779.6

(51) Int. Cl. H10B 12/00; H10D 1/68

(52) U.S. Cl. CPC H10B 12/482; H10B 12/03; H10B 12/05; H10B 12/488; H10D 1/714

(57) ABSTRACT

The present disclosure relates to a semiconductor device, a memory and a manufacturing method therefor, and an electronic device. The semiconductor device comprises: semiconductor layers (11), each having two opposite main surfaces, wherein the two opposite main surfaces are respectively a first side and a second side of the semiconductor layer (11), and the semiconductor layer (11) comprises a source contact region, a drain contact region, and a channel region between the source contact region and the drain contact region which are provided at intervals on the first side; bit lines (12), provided on the first sides of the semiconductor layers (11) and connected to the drain contact regions, wherein the bit lines (12) extend in a first direction, and the first direction is perpendicular to the surface of a substrate (2); and word lines (13), provided on the second sides of the semiconductor layers (11), wherein the word lines extend in a second direction, and the second direction is parallel to the surface of the substrate (2). The semiconductor device has a three-directional structure, and can increase the storage density.

### CROSS-REFERENCE TO RELATED APPLICATIONS

This application is a national stage of International Application No. PCT/CN2023/125603 filed on Oct. 20, 2023, which claims priority to Chinese Patent Application No. 202310428779.6 filed at China National Intellectual Property Administration (CNIPA) on Apr. 20, 2023 and entitled “SEMICONDUCTOR DEVICE, MEMORY AND MANUFACTURING METHOD THEREFOR, AND ELECTRONIC DEVICE”. The disclosures of these applications are hereby incorporated by reference in their entireties.

### TECHNICAL FIELD

The disclosure relates to the technical field of semiconductors, and in particular to, a semiconductor device, a memory and a method for preparing the same, and an electronic device.

### BACKGROUND

At present, a Dynamic Random Access Memory (DRAM) is usually fabricated by using a 2 Dimension (2D) or three dimensional (3D) structure, and sizes of bit lines (BLs), word lines (WLs), transistors or the like are reduced, to improve a storage density of the memory.

### SUMMARY

Based on the above, it is necessary to provide a semiconductor device, a memory and a method for preparing the same, and an electronic device, to address deficiencies in the related art.

The disclosure provides a semiconductor device, the semiconductor device is arranged on a substrate and includes semiconductor layers, BLs and WLs.

Each of the semiconductor layers is provided with two opposite main surfaces, the two opposite main surfaces are a first side and a second side of each of the semiconductor layers respectively, and each of the semiconductor layers includes, on the first side a source contact region and a drain contact region spaced apart from each other, and a channel region between the source contact region and the drain contact region.

Each of the BLs is arranged on the first side of a respective one of the semiconductor layers, is connected to the drain contact region, and extends along a first direction perpendicular to a surface of the substrate.

Each of the WLs is arranged on the second side of a respective one of the semiconductor layers, and extends along a second direction parallel to the surface of the substrate.

In some embodiments, the semiconductor device may further include capacitors, each of the capacitors is arranged on the first side of a respective one of the semiconductor layers and is connected to the source contact region.

In some embodiments, each of the semiconductor layers may surround a sidewall of a respective one of the WLs and is insulated from the respective one of the WLs, the first side of each of the semiconductor layers includes an upper surface, a lower surface and a side surface, and the source contact region, the drain contact region and the channel region are located at least on the side surface.

In some embodiments, each of the capacitors may include a first electrode, a second electrode and a dielectric layer between the first electrode and the second electrode.

The first electrode is connected to the source contact region and is provided with a cup-shaped cavity.

The second electrode is solidly filled in the cup-shaped cavity of the first electrode.

In some embodiments, each of the BLs may be in contact with the source contact region, and the first electrode is in contact with the drain contact region; the source contact region and the drain contact region have the interval there-between in the second direction.

In some embodiments, the semiconductor device may further include insulation structures, each of the insulation structures is located between a respective one of the BLs and the first electrode, and separates the respective one of the BLs, the channel region and the first electrode from each other.

In some embodiments, an orthographic projection of each of the BLs on a 2D plane formed by the first direction and the second direction may not be overlapped with an orthographic projection of the first electrode on the 2D plane.

The disclosure further provides a memory, the memory includes:
a substrate, a memory cell array, multiple BLs and multiple WLs.

The memory cell array includes multiple layers of memory cells stacked in a first direction, memory cells located in a same layer from the multiple layers of memory cells are arranged in columns in a second direction and arranged in rows in a third direction, the first direction is perpendicular to a surface of the substrate, the second direction is parallel to the surface of the substrate, and the third direction is parallel to the surface of the substrate and intersects with the second direction; each of the memory cells includes transistors, the transistor includes a semiconductor layer, the semiconductor layer is provided with two opposite main surfaces, the two opposite main surfaces are a first side and a second side of the semiconductor layer respectively, and the semiconductor layer includes, on the first side, a source contact region and a drain contact region spaced apart from each other, and a channel region between the source contact region and the drain contact region.

A same BL extending along the first direction from the multiple BLs is shared by all layers of memory cells located at a same position of the memory cell array, and each of the multiple BLs is arranged on the first side of a corresponding one of the semiconductor layers and is connected to the drain contact region of the corresponding one of the semiconductor layers.

A same WL extending along the second direction from the multiple WLs is shared by memory cells located in a same column among the memory cells located in the same layer, and each of the multiple WLs is arranged on the second side of a respective one of the semiconductor layers.

In some embodiments, each of the memory cells may further include capacitors, each of the capacitors is arranged on the first side of a respective one of the semiconductor layers and is connected to the source contact region.

In some embodiments, each of the capacitors may include a first electrode, a second electrode and a dielectric layer between the first electrode and the second electrode, the first electrode is provided with a cup-shaped cavity, the second electrode is solidly filled in the cup-shaped cavity of the first electrode.

An end of the second electrode extends along the first direction and the second direction.

Second electrodes of all layers of memory cells located at the same position of the memory cell array are connected integrally, and second electrodes of the memory cells located in the same column among the memory cells located in the same layer are connected integrally.

In some embodiments, in two memory cells adjacent to each other in the second direction among the memory cells located in the same layer, an orthographic projection of the BL corresponding to one of the two memory cells on a plane where the first direction intersects with the second direction may be partially overlapped with an orthographic projection of the first electrode of another one of the two memory cells on the plane.

In some embodiments, two memory cells adjacent to each other in the third direction among the memory cells located in the same layer may form a memory group, second electrodes of two memory cells from a same memory group are interconnected, and the two memory cells are symmetrically arranged with respect to a symmetry center of an interconnected structure of the second electrodes.

The memory may further include multiple first isolation structures and multiple second isolation structures.

Each of the first isolation structures is located between two memory groups adjacent to each other in the second direction, and covers at least sidewalls of a corresponding one of the semiconductor layers, a corresponding one of the BLs and the first electrode of a corresponding one of the capacitors in the third direction.

Each of the second isolation structures is located between two memory groups adjacent to each other in the third direction, covers at least sidewalls of a corresponding one of the WLs and a corresponding one of the semiconductor layers in the second direction, and is correspondingly connected to a respective one of the first isolation structures.

In some embodiments, the memory may further include multiple third isolation structures, the multiple third isolation structures are located between different layers of memory groups adjacent to each other in the first direction.

Each of the first isolation structures and each of the second isolation structures extend along the first direction, and are connected to a respective one of the third isolation structures.

The disclosure further provides a method for preparing a memory, the method includes the following operations.

A substrate is provided, and multilayer stacked units are formed on the substrate, where each of the multilayer stacked units includes sacrificial layers and interlayer dielectric layers sequentially and alternately stacked along a first direction perpendicular to a surface of the substrate.

A sidewall of each sacrificial layer in a second direction is back etched to form a first accommodation groove, and an initial semiconductor layer, a gate dielectric layer and a WL are sequentially formed on an inner wall of the first accommodation groove, the second direction is parallel to the surface of the substrate.

The sacrificial layers, the interlayer dielectric layers and the initial semiconductor layers are etched along the first direction, to separate the initial semiconductor layer into multiple semiconductor layers arranged at intervals in the second direction, each of the semiconductor layers is provided with two opposite main surfaces, the two opposite main surfaces are a first side away from the WL and a second side facing towards the WL respectively, and each of the semiconductor layers includes, on the first side, a source contact region and a drain contact region spaced apart from each other, and a channel region between the source contact region and the drain contact region.

A BL hole, which penetrates the multilayer stacked unit in the first direction and exposes the drain contact region of each corresponding layer, is formed in a first area of the multilayer stacked unit.

A BL is formed in the BL hole.

An etching groove which penetrates the multilayer stacked unit in the first direction and extends along the second direction, is formed in a second area of each of the multilayer stacked units, each second area has a spacing from the first area in a third direction, and the second direction and the third direction are parallel to the surface of the substrate and intersect with each other.

The sacrificial layer is etched, to form a second accommodation groove and expose the source contact region of a corresponding layer, where the second accommodation groove has a spacing from the BL hole in each of the second direction and the third direction.

A capacitor is formed in the second accommodation groove.

In some embodiments, the method may further include the following operations before the operation of forming, in the first area of the multilayer stacked unit, the BL hole which penetrates the multilayer stacked unit in the first direction and exposes the drain contact region of each corresponding layer.

A spacing hole, which penetrates the multilayer stacked unit in the first direction and exposes the channel region of each corresponding layer, is formed in a third area of the multilayer stacked unit, the third area defines the spacing between the BL hole and the second accommodation groove.

An insulation structure is formed in the spacing hole.

The second accommodation groove further exposes a sidewall of the insulation structure away from the channel region.

In some embodiments, the method may further include the following operations after the operation of etching the sacrificial layers, the interlayer dielectric layers and the initial semiconductor layers along the first direction, to separate the initial semiconductor layer into the multiple semiconductor layers arranged at intervals in the second direction.

A first isolation structure is formed in an etched area of each of the sacrificial layer, the interlayer dielectric layer and the initial semiconductor layer, the first isolation structure is located between semiconductor layers adjacent to each other in the second direction from the multiple semiconductor layers, extends along the third direction, and is provided with a bending portion bent along the second direction.

The BL is located in an area surrounded by the drain contact region, the first isolation structure and the insulation structure.

In some embodiments, the operation of forming the multilayer stacked units on the substrate may include the following operations.

Sacrificial material layers and interlayer dielectric material layers are sequentially and alternately stacked along the first direction, to form a stacked structure.

The stacked structure is etched along the first direction, to form multiple first trenches extending along the second direction and arranged at intervals, and form the multilayer stacked units located on two sides of each of the first trenches along the third direction.

The operation of sequentially forming the initial semiconductor layer, the gate dielectric layer and the WL on the inner wall of the first accommodation groove may further include the following operations. Semiconductor material layers, gate dielectric material layers and WL material layers are sequentially formed on the first trenches and the inner walls of the first accommodation grooves that have two ends communicating with each other. The semiconductor material layer, the gate dielectric material layer and the WL material layer in each of the first trenches are removed, such that the semiconductor material layer retained in the first accommodation groove constitutes the initial semiconductor layer, the gate dielectric material layer retained in the first accommodation groove constitutes the gate dielectric layer, and the WL material layer retained in the first accommodation groove constitutes the WL.

The method may further include the following operation. A second isolation structure is formed in each of the first trenches.

The disclosure further provides an electronic device, the electronic device includes the semiconductor device provided in any one of the foregoing embodiments of the claims or the memory provided in any one of the foregoing embodiments.

Details of one or more embodiments of the disclosure will be set forth in the following drawings and descriptions. Other features, objects and advantages of the disclosure will become apparent from the description, drawings and claims.

### BRIEF DESCRIPTION OF THE DRAWINGS

In order to explain technical solutions in the embodiments of the disclosure more clearly, the drawings required to be used in descriptions of the embodiments will be briefly introduced below. It is apparent that the drawings described below are only some of the embodiments of the disclosure, and other drawings may also be obtained by those of ordinary skill in the art according to these drawings without paying any creative work.

FIG. 1 is a schematic cross-sectional structural diagram of a semiconductor device provided in some embodiments of the disclosure; FIG. 1 is also a schematic cross-sectional structural diagram of a memory provided in some embodiments of the disclosure.

FIG. 2 is a schematic cross-sectional structural diagram of the semiconductor device shown in FIG. 1 in a AA′ direction.

FIG. 3 is a schematic cross-sectional structural diagram of the semiconductor device shown in FIG. 1 in a BB′ direction.

FIG. 4 is a schematic cross-sectional structural diagram of the semiconductor device shown in FIG. 1 in a CC′ direction.

FIG. 5 is a schematic cross-sectional structural diagram of the semiconductor device shown in FIG. 1 in a DD′ direction.

FIG. 6 is a schematic cross-sectional structural diagram of the semiconductor device shown in FIG. 1 in a EE′ direction.

FIG. 7 is an equivalent circuit diagram of a semiconductor device provided in some embodiments of the disclosure.

FIG. 8 is an equivalent circuit diagram of a memory provided in some embodiments of the disclosure.

FIG. 9 is a schematic cross-sectional structural diagram of a memory provided in some other embodiments of the disclosure.

FIG. 10 is a schematic flowchart of a method for preparing a memory provided in some embodiments of the disclosure.

FIG. 11 is a schematic flowchart of an operation S100 in the method for preparing the memory provided in some embodiments of the disclosure.

FIG. 12 is a schematic cross-sectional structural diagram of an obtained structure after a stacked structure is formed on a substrate in some embodiments of the disclosure.

FIG. 13 is a schematic cross-sectional structural diagram of the obtained structure shown in FIG. 12 in a AA′ direction.

FIG. 14 is a schematic cross-sectional structural diagram of an obtained structure after multilayer stacked units are formed in some embodiments of the disclosure.

FIG. 15 is a schematic cross-sectional structural diagram of the obtained structure shown in FIG. 14 in a AA′ direction.

FIG. 16 is a schematic cross-sectional structural diagram of an obtained structure after initial semiconductor layers are formed in some embodiments of the disclosure.

FIG. 17 is a schematic cross-sectional structural diagram of the obtained structure shown in FIG. 16 in a AA′ direction.

FIG. 18 is a schematic cross-sectional structural diagram of an obtained structure after gate dielectric layers and WLs are formed in some embodiments of the disclosure.

FIG. 19 is a schematic cross-sectional structural diagram of the obtained structure shown in FIG. 18 in a AA′ direction.

FIG. 20 is a schematic cross-sectional structural diagram of an obtained structure after second isolation structures are formed in some embodiments of the disclosure.

FIG. 21 is a schematic cross-sectional structural diagram of the obtained structure shown in FIG. 20 in a AA′ direction.

FIG. 22 is a schematic cross-sectional structural diagram of an obtained structure after first isolation structures are formed in some embodiments of the disclosure.

FIG. 23 is a schematic cross-sectional structural diagram of the obtained structure shown in FIG. 22 in a BB′ direction.

FIG. 24 is a schematic cross-sectional structural diagram of the obtained structure shown in FIG. 22 in a CC′ direction.

FIG. 25 is a schematic cross-sectional structural diagram of an obtained structure after spacing holes are formed in some embodiments of the disclosure.

FIG. 26 is a schematic cross-sectional structural diagram of the obtained structure shown in FIG. 25 in a AA′ direction.

FIG. 27 is a schematic cross-sectional structural diagram of an obtained structure after insulation structures are formed in some embodiments of the disclosure.

FIG. 28 is a schematic cross-sectional structural diagram of the obtained structure shown in FIG. 27 in a AA′ direction.

FIG. 29 is a schematic cross-sectional structural diagram of an obtained structure after BL holes are formed in some embodiments of the disclosure.

FIG. 30 is a schematic cross-sectional structural diagram of the obtained structure shown in FIG. 29 in a BB′ direction.

FIG. 31 is a schematic cross-sectional structural diagram of an obtained structure after BLs are formed in some embodiments of the disclosure.

FIG. 32 is a schematic cross-sectional structural diagram of the obtained structure shown in FIG. 31 in a BB′ direction.

FIG. 33 is a schematic cross-sectional structural diagram of an obtained structure after etching grooves are formed in some embodiments of the disclosure.

FIG. 34 is a schematic cross-sectional structural diagram of the obtained structure shown in FIG. 33 in a AA′ direction.

FIG. 35 is a schematic cross-sectional structural diagram of an obtained structure after second accommodation grooves are formed in some embodiments of the disclosure.

FIG. 36 is a schematic cross-sectional structural diagram of the obtained structure shown in FIG. 35 in a AA′ direction.

FIG. 37 is a schematic cross-sectional structural diagram of an obtained structure after a first electrode material layer is formed in some embodiments of the disclosure.

FIG. 38 is a schematic cross-sectional structural diagram of the obtained structure shown in FIG. 37 in a AA′ direction.

FIG. 39 is a schematic cross-sectional structural diagram of an obtained structure after first electrodes are formed in some embodiments of the disclosure.

FIG. 40 is a schematic cross-sectional structural diagram of the obtained structure shown in FIG. 39 in a AA′ direction.

### DETAILED DESCRIPTION

In order to facilitate understanding the disclosure, the disclosure will be described more completely below with reference to relevant drawings. Preferred embodiments of the disclosure are given in the drawings. However, the disclosure may be implemented in many different forms and is not limited to the embodiments described here. On the contrary, a purpose of providing these embodiments is to make contents disclosed in the disclosure more thorough and comprehensive.

Unless otherwise defined, all technical and scientific terms used here have the same meaning as those usually understood by technicians in the technical field to which the disclosure belongs. Here, the terms used in the description of the disclosure are only for the purpose of describing specific embodiments, and are not intended to limit the disclosure.

It should be understood that when an element or layer is referred to as being “on”, “adjacent to” or “connected to” other elements or layers, the element or layer may be directly on, adjacent to or connected to other elements or layers, or there may be elements or layers interposed there-between. It should be understood that although various elements, components, regions, layers, doping types and/or portions may be described by using terms “first”, “second”, “third” or the like, these elements, components, regions, layers, doping types and/or portions should not be limited by these terms. These terms are only intended to distinguish one element, component, region, layer, doping type or portion from another element, component, region, layer, doping type or portion. Therefore, without departing from teachings of the disclosure, a first element, component, region, layer, doping type or portion as discussed below may be represented as a second element, component, region, layer or portion. For example, a first contact region may be referred to as a second contact region, and similarly, a second contact region may be referred to as a first contact region; the first contact region and the second contact region are different contact regions.

Terms of spatial relationships such as “above” may be used here, to describe relationships between an element or feature shown in the drawings and other elements or features. It should be understood that in addition to orientations shown in the drawings, the terms of spatial relationships further include different orientations of a device in use and operation. For example, if the device in the drawings is flipped, an element or feature described as being “above other elements” will be oriented as being “below” other elements or features. Therefore, an exemplary term “above” may include both “above” and “below” orientations. Furthermore, the device may also include additional orientations (such as, rotated by 90 degrees or other orientations), and spatial descriptors used here are interpreted correspondingly.

Singular forms “a”, “an” and “said/the” may also include plural forms when they are used here, unless otherwise indicated by the context clearly. It should also be understood that when terms “constitute” and/or “include” are used in the description, presence of stated features, entireties, steps, operations, elements and/or components may be determined; however, presence or addition of one or more other features, entireties, steps, operations, elements, components, and/or combinations thereof is not excluded. At the same time, when a term “and/or” is used here, this term includes any and all combinations of relevant listed items.

The embodiments of the disclosure are described here with reference to cross-sectional diagrams that are schematic diagrams of idealized embodiments (and intermediate structures) of the disclosure, such that variations in shapes shown due to for example fabrication technologies and/or tolerances may be anticipated. Therefore, the embodiments of the disclosure should not be limited to particular shapes of regions shown here, instead, include deviations in shapes due to for example fabrication technologies. The regions shown in the drawings are substantially schematic, and their shapes do not represent actual shapes of regions of devices, and do not limit the scope of the disclosure.

In view of the foregoing deficiencies in the related art, the disclosure provides a semiconductor device, a memory and a method for preparing the same, and an electronic device, of which details will be described in subsequent embodiments.

The embodiments of the disclosure provide a new three dimensional (3D) stacked transistor or memory architecture, a new structural design, and a new process flow. Of course, the design is also applicable to a memory array in a 2 Dimension (2D) plane.

According to some embodiments of the disclosure, there is provided a semiconductor device. The semiconductor device may be arranged on a substrate, but is not limited thereto. For example, the semiconductor device may be understood as a semiconductor device on a logic circuit.

The semiconductor device may be transistor(s), or a memory cell containing transistor(s), or a memory containing transistors, or a product containing transistors such as a 3D memory or a semiconductor chip, etc.

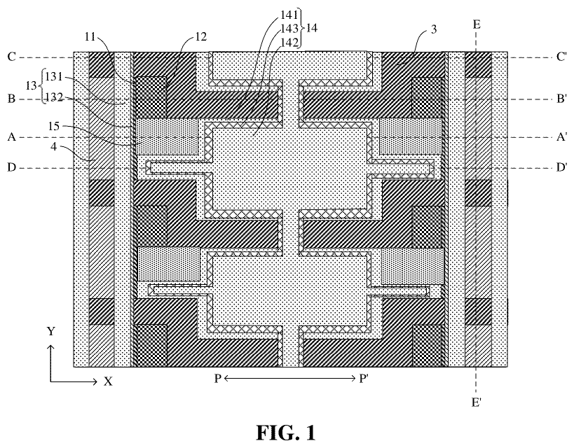

An example is a semiconductor device shown in FIG. 1 to FIG. 6, the semiconductor device is arranged on a substrate 2, and the semiconductor device may specifically include semiconductor layers 11, bit lines (BLs) 12, and word lines (WLs) 13. The semiconductor layer is used as a channel of a transistor.

Each of the semiconductor layers 11 is in a shape of a film layer, and may be provided with two opposite main surfaces. It may be understood that the two opposite main surfaces are used as a first side and a second side of each of the semiconductor layers respectively. Each of the semiconductor layers 11 may include, on the first side a source contact region and a drain contact region spaced apart from each other, and a channel region between the source contact region and the drain contact region.

Each of the BLs 12 is arranged on the first side of a respective one of the semiconductor layers 11, is connected to the drain contact region, and extends along a first direction. In the embodiment of the disclosure, the first direction is perpendicular to a surface of the substrate 2, such as a Z direction. Each of the BLs may be directly connected to the drain contact region, or may be connected to the drain contact region through a conductive layer made of other materials. In an implementation, each of the BLs is directly in contact with the drain contact region of a respective one of the semiconductor layers 11, which is beneficial to miniaturize the device. Each of the BLs 12 extends along the first direction. In an implementation, each of the BLs may be filled and extend in a respective one of through holes perpendicular to the substrate, and the through holes may be vertical holes.

Each of the WLs 13 is arranged on the second side of a respective one of the semiconductor layers 11, and extends along a second direction. In the embodiment of the disclosure, the second direction is parallel to the surface of the substrate 2, such as a Y direction in a 2D plane parallel to the substrate.

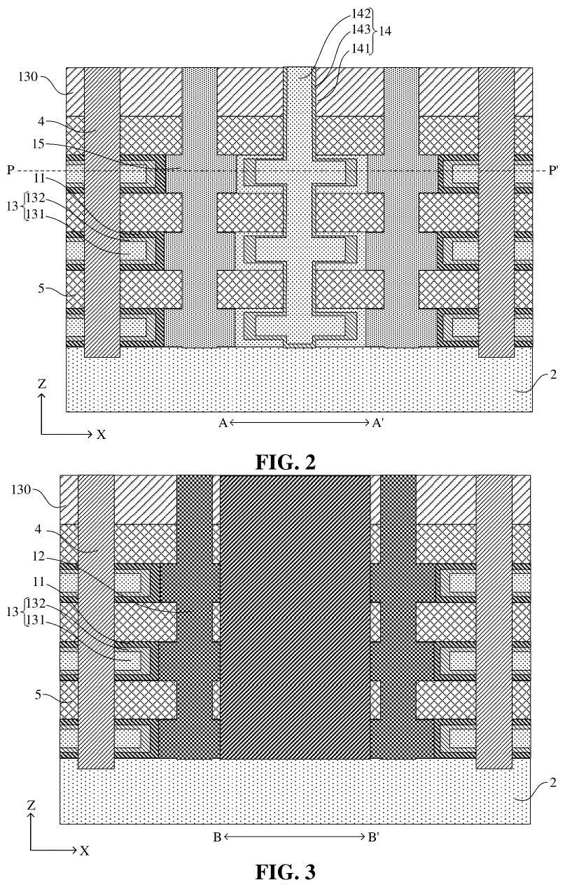

It should be noted that FIG. 1 is a schematic cross-sectional structural diagram of a structure shown in FIG. 2 in a PP′ direction. The source contact region of each of the semiconductor layers is connected to other devices, and types of other devices depend on an application scenario of the transistor or semiconductor device. For example, when the semiconductor device is used in a 1T1C memory cell scenario, the source contact region is connected to an electrode of a capacitor. If the semiconductor device is used in a 2T0C scenario, the semiconductor device may be used as a write transistor, and a source contact region of the write transistor is connected to a read transistor.

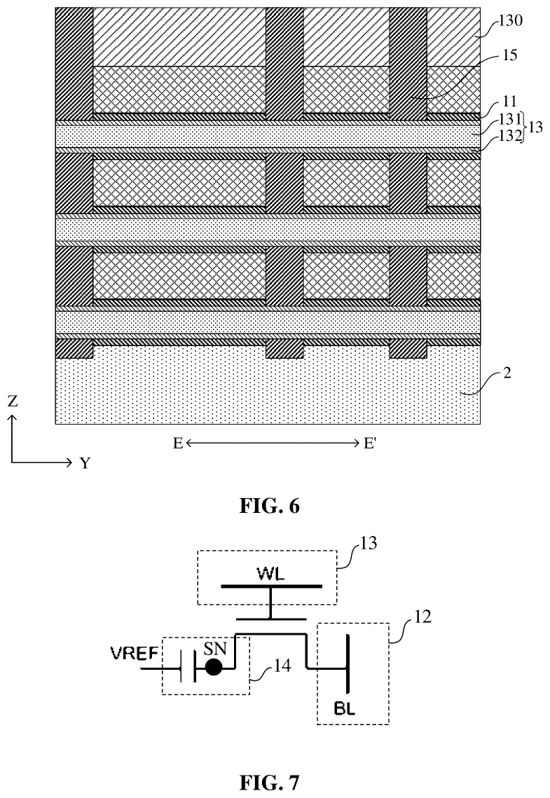

If the semiconductor device provided in the above embodiments is applied to the 1T1C memory cell scenario, an equivalent circuit diagram of a 1T1C semiconductor device may be shown in FIG. 7. In the semiconductor device provided in the above embodiments, a semiconductor device with a 3D structure is achieved by providing BLs 12 perpendicular to the surface of the substrate 2 and WLs 13 parallel to the surface of the substrate 2, therefore it is beneficial to improve a storage density. Furthermore, with the above structure, the semiconductor device may also have higher read, write and refresh speeds while achieving 3D storage to improve the storage density.

Materials of the semiconductor layers 11 are not specifically limited in the disclosure. As an example, the semiconductor layers 11 may be made of polycrystalline silicon, amorphous silicon, indium gallium zinc oxide (IGZO), indium zinc oxide (IZO), indium tin oxide (ITO), zinc oxide (ZnO), or any combination of their material types. Alternatively, the semiconductor layers 11 may also be made of 2D materials such as graphene, molybdenum disulfide (MoS₂), etc.

When the semiconductor layer 11 is made of IGZO, it may reduce a leakage current of the semiconductor device and ensure device reliability of the semiconductor device, it may also allow the semiconductor device to have advantages such as a short read time, a short write time, a short refresh time, etc.

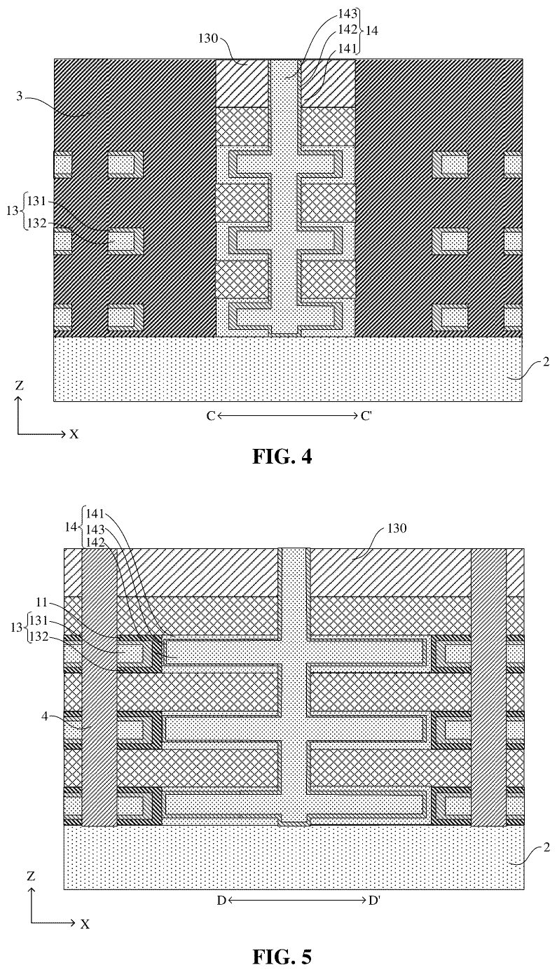

With continuous reference to FIG. 1, FIG. 2, FIG. 4 and FIG. 5, in some embodiments, the semiconductor device may further include capacitors 14.

Each of the capacitors 14 may be arranged on the first side of a respective one of the semiconductor layers 11, and may be connected to the source contact region.

In the semiconductor device provided in the above embodiments, each of the capacitors 14 and each of the BLs 12 are located on the same side of a respective one of the semiconductor layers 11 by arranging each of the capacitors 14 on the first side of the respective one of the semiconductor layers 11, to achieve a 1T1C semiconductor device with a 3D structure.

With continuous reference to FIG. 2, FIG. 3 and FIG. 5, in some embodiments, each of the semiconductor layers 11 surrounds a sidewall of a respective one of the WLs 13, and is insulated from the respective one of the WLs 13. In this embodiment, the first side of each of the semiconductor layers 11 includes an upper surface, a lower surface and a side surface, and the source contact region, the drain contact region and the channel region are located at least on the side surface. The upper surface and the lower surface extend along a direction parallel to the substrate, and the side surface extends along a direction perpendicular to the substrate. The upper surface, the side surface and the lower surface are sequentially connected to form a continuous surface.

It may be understood that in the semiconductor device provided in the above embodiments, the second side of each of the semiconductor layers 11 faces a respective one of the WLs 13.

Constituent materials of the BLs 12 are not specifically limited in the embodiments of the disclosure. As an example, the constituent materials of the BLs 12 may include, but are not limited to elements containing titanium (Ti) or tungsten (W). Constituent materials of the WLs 13 are not specifically limited in the embodiments of the disclosure, either. As an example, the constituent materials of the WLs 13 may include metal elements, and metals such as tungsten or copper (Cu).

With continuous reference to FIG. 1 to FIG. 6, in some embodiments, the semiconductor device may further include gate dielectric layers 131, each of the gate dielectric layers 131 is arranged around a sidewall of a respective one of the WLs 13.

The semiconductor layer and gate insulation layer surround at least three faces of the sidewall of an entire WL, and each has a shape adapted to that of the gate or the WL. Alternatively, the semiconductor layer, the gate insulation layer and the WL are sequentially formed in a trench extending along the direction parallel to the substrate. The trench is a trench formed by continuously etching a sidewall of a longitudinally extended trench along a lateral direction.

As an example, constituent materials of the gate dielectric layers 131 may include silicon dioxide (SiO₂), silicon oxynitride (SiON), silicon nitride, aluminum oxide (Al₂O₃), aluminum oxynitride (AION) or the like; the constituent materials may be a high-k dielectric material (a dielectric material with a dielectric constant equal to or greater than 3.9), or a low-k dielectric material (a dielectric constant equal to or greater than 2.5 and less than 3.9), an ultra-low-k dielectric material (a dielectric constant less than 2.5), a ferroelectric material, an anti-ferroelectric material, silicon carbide (SiC), or any combination thereof.

With continuous reference to FIG. 1, FIG. 2, FIG. 4 and FIG. 5, in some embodiments, each of the capacitors 14 may include a first electrode 141, a second electrode 142, and a dielectric layer 143 between the first electrode 141 and the second electrode 142. The dielectric layer 143 may also be made of a high-k dielectric material.

The first electrode 141 may be connected to the source contact region and is provided with a cup-shaped cavity; the second electrode 142 may be solidly filled in the cup-shaped cavity of the first electrode 141. The second electrode 142 extends along the lateral direction (the direction parallel to the substrate), and the cup-shaped cavity is wrapped around an outer wall of the second electrode. The first electrode and the second electrode may be formed in a laterally extended cavity, opening of the cavity is away from the source contact region, the cavity exposes the source contact region of a respective one of the semiconductor layers and is insulated from a respective one of the BLs, bottom of the cavity is close to the source contact region, a sidewall of the cavity has four faces, upper and lower surfaces are parallel to the substrate, the sidewall is an insulation layer, conductive layers are deposited on the sidewall and the bottom respectively by for example Atomic Layer Deposition (ALD), a capacitor dielectric layer 143 is continuously deposited, and a conductor material is continuously filled in the cavity to form the second electrode 142.

As shown in FIG. 7, in the semiconductor device provided in the above embodiments, the first electrode 141 may be used as a storage node (SN) by contacting and connecting to the source contact region, and the second electrode 142 may be connected to a reference voltage VREF.

With continuous reference to FIG. 1 and FIG. 2, in some embodiments, each of the BLs 12 is in contact with the source contact region, the first electrode 14 is in contact with the drain contact region, and the source contact region and the drain contact region are sequentially arranged in the second direction (such as the Y direction) with an interval there-between.

With continuous reference to FIG. 1 and FIG. 2, in some embodiments, the semiconductor device may further include insulation structures 15, each of the insulation structures 15 is located between a respective one of the BLs 12 and the first electrode 141. Each of the insulation structures 15 may separate the respective one of the BLs 12, the channel region and the first electrode 141 from each other. Each of the insulation structures 15 may be a through hole formed perpendicular to the substrate at this position, and an insulation medium is filled in the through hole, to be used as the insulation structure.

As an example, each of the insulation structures 15 may be in contact with the channel region and extend along the first direction (such as the Z direction).

Constituent materials of the insulation structures 15 are not specifically limited in the embodiments of the disclosure. As an example, the insulation structures 15 may be made of dielectric materials. Exemplarily, the dielectric materials may include silicon nitride, silicon dioxide (SiO₂), etc.

With continuous reference to FIG. 1, an orthographic projection of each of the BLs 12 on a 2D plane formed by the first direction (such as the Z direction) and the second direction (such as the Y direction) is not overlapped with an orthographic projection of the first electrode 141 on the 2D plane. In this way, it is beneficial to reduce a parasitic capacitance between each of the BLs 12 and the first electrode 141, reduce distortion of a signal due to energy loss during transmission of the signal, and improve electrical performance of the semiconductor device.

According to some embodiments, the disclosure further provides a memory, the memory includes the above semiconductor device.

With continuous reference to FIG. 1 to FIG. 6, in some embodiments, the memory may include a substrate 2, multiple BLs 12, multiple WLs 13, and a memory cell array. The memory cell array is arranged in a 2D plane and has one or more layers.

In some embodiments, the memory cell array includes multiple layers of memory cells stacked in a first direction, memory cells located in a same layer from the multiple layers of memory cells are arranged in columns in a second direction and arranged in rows in a third direction. The first direction is perpendicular to a surface of the substrate 2, such as a Z direction; the second direction is parallel to the surface of the substrate 2, such as a Y direction; and the third direction is parallel to the surface of the substrate 2 and intersects with the second direction, such as an X direction.

Each of the memory cells may include transistor(s). The transistor may include a semiconductor layer 11. The semiconductor layer 11 is provided with two opposite main surfaces, the two opposite main surfaces are a first side and a second side respectively. The semiconductor layer 11 may include, on the first side, a source contact region and a drain contact region spaced apart from each other, and a channel region between the source contact region and the drain contact region.

A same BL 12 extending along the first direction (such as the Z direction) from the multiple BLs is shared by all layers of memory cells located at a same position of the memory cell array, and each of the multiple BLs 12 is arranged on the first side of a corresponding one of the semiconductor layers 11 and is connected to the drain contact region of the corresponding one of the semiconductor layers 11. A same WL 13 extending along the second direction (such as the Y direction) from the multiple WLs is shared by memory cells located in a same column among the memory cells located in the same layer, and each of the multiple WLs 13 is arranged on the second side of a respective one of the semiconductor layers 11.

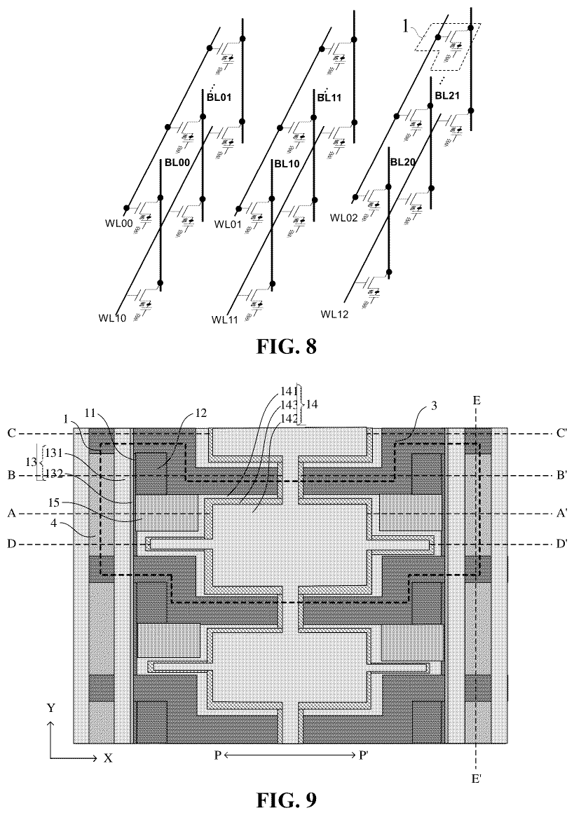

An equivalent circuit diagram of the memory provided in the above embodiments may be shown in FIG. 8. Multiple memory cells are stacked in multiple layers in a direction perpendicular to the substrate 2 and are arranged in an array in a same layer, to form the memory cell array. Such structure occupies a small area and has a high space utilization, which is beneficial to improve a storage density of the memory.

It should be noted that in the memory provided in the embodiments of the disclosure, the transistors included in the memory cells may be the semiconductor device provided in any one of the foregoing embodiments, and its equivalent circuit diagram may refer to FIG. 7.

With continuous reference to FIG. 1, FIG. 2, FIG. 4 and FIG. 5, in the memory provided in some embodiments, the transistor in each of the memory cells may further include capacitors 14.

Each of the capacitors 14 may be arranged on the first side of a respective one of the semiconductor layers 11 and is connected to the source contact region.

With continuous reference to FIG. 1, FIG. 2, FIG. 4 and FIG. 5, in some embodiments, each of the capacitors 14 may specifically include a first electrode 141, a second electrode 142, and a dielectric layer 143 between the first electrode 141 and the second electrode 142. The first electrode 141 may be provided with a cup-shaped cavity, the second electrode 142 may be filled in the cup-shaped cavity of the first electrode 141. The second electrode may be a cavity structure or a solid structure.

As shown in FIG. 1, FIG. 2, FIG. 4 and FIG. 5, an end of the second electrode 142 extends along the first direction (such as the Z direction) and the second direction (such as the Y direction). Second electrodes 142 of all layers of memory cells located at the same position of the memory cell array are connected integrally, and second electrodes 142 of the memory cells located in the same column among the memory cells located in the same layer are connected integrally.

In the memory provided in the above embodiments, as an example, the first electrode 141 may be used as an SN by connecting to the source contact region, and the second electrode 142 may be connected to a reference voltage VREF.

In some embodiments, in two memory cells adjacent to each other in the second direction (such as the Y direction) among the memory cells located in the same layer, an orthographic projection of the BL 12 corresponding to one of the two memory cells on a plane where the first direction (such as the Z direction) intersects with the second direction (such as the Y direction) is partially overlapped with an orthographic projection of the first electrode 141 of another one of the two memory cells on the plane. In this way, it is beneficial to further miniaturize size of the memory.

In order to facilitate descriptions, with reference to FIG. 9, the memory provided in some embodiments of the disclosure will described in more detail below, by taking an example that two memory cells adjacent to each other in the third direction (such as the X direction) among the memory cells located in the same layer form a memory group 1. Second electrodes 142 of two memory cells from a same memory group 1 are interconnected, and the two memory cells are symmetrically arranged with respect to a symmetry center of an interconnected structure of the second electrodes 142. It should be noted that similar to FIG. 1, FIG. 9 is also a schematic cross-sectional structural diagram of the structure shown in FIG. 2 in the PP′ direction.

As shown in FIG. 9, in some embodiments, the memory may further include multiple first isolation structures 3 and multiple second isolation structures 4.

Each of the first isolation structures 3 is located between two memory groups 1 adjacent to each other in the second direction (such as the Y direction), and covers at least sidewalls of a corresponding one of the semiconductor layers 11, a corresponding one of the BLs 12 and the first electrode 141 of a corresponding one of the capacitors 14 in the third direction (such as the X direction). Each of the second isolation structures 4 is located between two memory groups 1 adjacent to each other in the third direction (such as the X direction), covers at least sidewalls of a corresponding one of the WLs 13 and a corresponding one of the semiconductor layers 11 in the second direction (such as the Y direction), and is correspondingly connected to a respective one of the first isolation structures 13.

As an example, constituent materials of the first isolation structures 3 may include, but are not limited to one or more of oxides, nitrides, oxynitrides and carbides. Exemplarily, the oxides may include silicon dioxide (SiO₂), the nitrides may include silicon nitride, the oxynitrides may include silicon oxynitride, and the carbides may include silicon carbide. Constituent materials of the second isolation structures 4 may be the same as or different from the constituent materials of the first isolation structures 3.

With continuous reference to FIG. 2 to FIG. 6, in some embodiments, the memory may further include multiple third isolation structures 5, the multiple third isolation structures 5 are arranged between different layers of memory groups 1 adjacent to each other in the first direction (such as the Z direction).

In the memory provided in the above embodiments, each of the first isolation structures 3 and each of the second isolation structures 4 extend along the first direction (such as the Z direction), and are connected to a respective one of the third isolation structures 5.

According to some embodiments, the disclosure further provides a method for preparing a memory. The method for preparing a memory may be used for preparing the memory provided in any one of the foregoing embodiments such as any one of memories shown in FIG. 1 to FIG. 9. Therefore, technical features of the method and the memory may be replaced by each other and supplemented with each other without conflict, such that those skilled in the art may learn about technical contents of the disclosure.

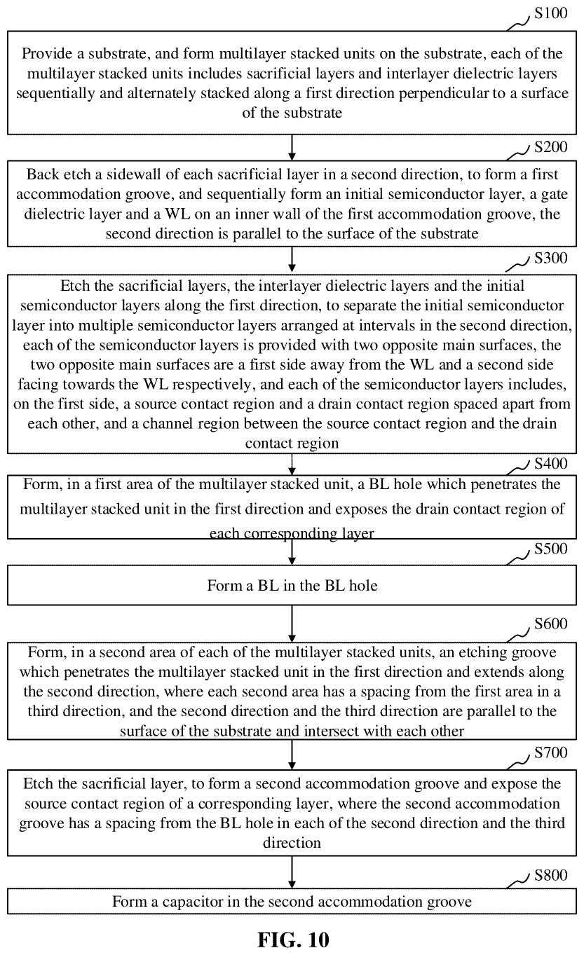

With reference to FIG. 10, in some embodiments, the method for preparing a memory may specifically include the following operations S100 to S800.

In operation S100, a substrate is provided, and multilayer stacked units are formed on the substrate, each of the multilayer stacked units includes sacrificial layers and interlayer dielectric layers sequentially and alternately stacked along a first direction perpendicular to a surface of the substrate; and a trench is present between adjacent multilayer stacked units, and exposes end surfaces of the sacrificial layer and the interlayer dielectric layer of each of the adjacent multilayer stacked units.

In operation S200, a sidewall of each sacrificial layer in a second direction is back etched, which may be understood as back etching the end surface of the sacrificial layer, to form a first accommodation groove, and an initial semiconductor layer, a gate dielectric layer and a WL are sequentially formed on only an inner wall of the first accommodation groove, the second direction is parallel to the surface of the substrate.

In operation S300, the sacrificial layers, the interlayer dielectric layers and the initial semiconductor layers are etched along the first direction, to separate the initial semiconductor layer into multiple semiconductor layers arranged at intervals in the second direction, each of the semiconductor layers is provided with two opposite main surfaces, the two opposite main surfaces are a first side away from the WL and a second side facing towards the WL respectively, and each of the semiconductor layers includes, on the first side, a source contact region and a drain contact region spaced apart from each other, and a channel region between the source contact region and the drain contact region.

In operation S400, a BL hole, which penetrates the multilayer stacked unit in the first direction and exposes the drain contact region of each corresponding layer, is formed in a first area of the multilayer stacked unit.

In operation S500, a BL is formed in the BL hole.

In operation S600, an etching groove which penetrates the multilayer stacked unit in the first direction and extends along the second direction, is formed in a second area of each of the multilayer stacked units, each second area has a spacing from the first area in a third direction, and the second direction and the third direction are parallel to the surface of the substrate and intersect with each other.

In operation S700, the sacrificial layer is etched, to form a second accommodation groove and expose the source contact region of a corresponding layer, where the second accommodation groove has a spacing from the BL hole in each of the second direction and the third direction.

In operation S800, a capacitor is formed in the second accommodation groove.

In the method for preparing the memory provided in the above embodiments, not only multiple memory cells stacked in multiple layers in the direction perpendicular to the substrate and arranged in an array in a same layer may be formed, but also semiconductor layers, BLs, WLs and capacitors of the multiple memory cells may be synchronously generated in a same operation. For example, BLs of multiple different memory cells may be synchronously generated in the same operation. Therefore, with the method in the embodiment of the disclosure, preparation processes of the memory may also be simplified, thereby improving production efficiency and yield, and reducing process cost and budget.

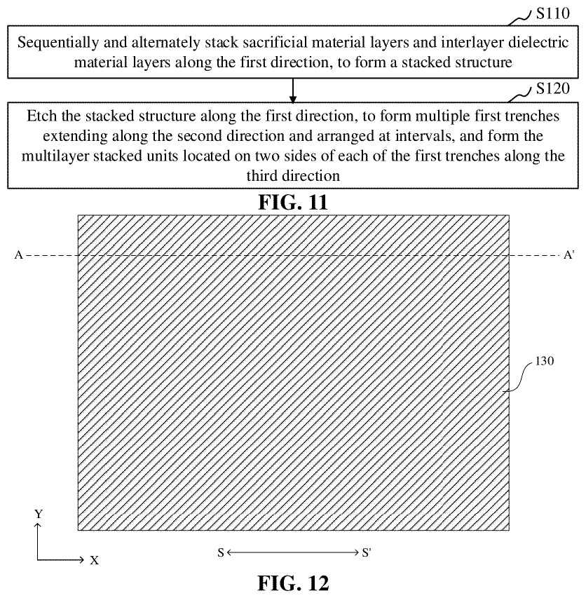

With reference to FIG. 11, in some embodiments, the operation of forming the multilayer stacked units on the substrate from the operation S100 may specifically include the following operations S110 and S120.

In operation S110, sacrificial material layers and interlayer dielectric material layers are sequentially and alternately stacked along the first direction, to form a stacked structure.

In operation S120, the stacked structure is etched along the first direction, to form multiple first trenches extending along the second direction and arranged at intervals, and form the multilayer stacked units located on two sides of each of the first trenches along the third direction.

It should be understood that although operations in the flowcharts of FIG. 10 and FIG. 11 are sequentially displayed according to indications of arrows, these operations are not necessarily sequentially executed in an order indicated by the arrows. Unless clearly explained here, there is no strict order limitation on execution of these operations, and these operations may be executed in other orders. Furthermore, at least a part of the operations in FIG. 10 may include multiple operations or multiple stages, these operations or stages are not necessarily completed at the same time, instead, these operations or stages may be executed at different times; and an execution order of these operations or stages is not necessarily to be sequential execution either, instead, these operations or stages may be executed in turn or alternately with other operations or at least a part of operations or stages from other operations.

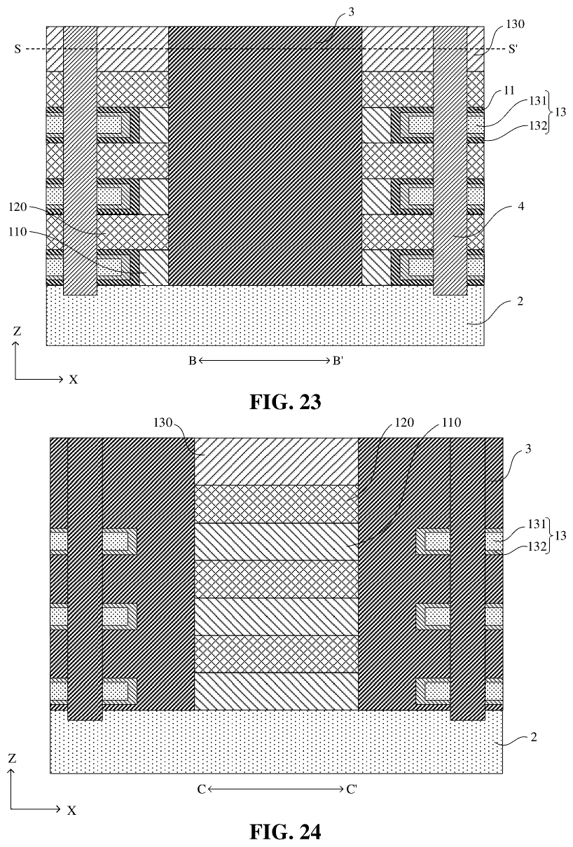

In order to explain the method for preparing the memory in some of the above embodiments more clearly, some embodiments of the disclosure will be understood below with reference to FIG. 1 to FIG. 9 and FIG. 12 to FIG. 40.

In the operation S100, with reference to FIG. 12 to FIG. 15, a substrate 2 is provided.

Multiple multilayer stacked units U are formed on the substrate 2. Each of the multilayer stacked units U may include sacrificial layers 110 and interlayer dielectric layers 120 sequentially and alternately stacked along a first direction perpendicular to a surface of the substrate 2.

Specifically, multiple film layers used as sacrificial layers and multiple film layers used as interlayer dielectric layers are deposited on the substrate 2 to form stacked layers, and the stacked layers are patterned to form multiple multilayer stacked units U distributed at intervals on the substrate and independent of each other. Specifically, multiple trenches extending along a column direction and spaced apart in a row direction are formed on the stacked layers, and each of the trenches penetrates a respective one of the stacked layers. One of the stacked layers between two adjacent trenches is a respective one of the multilayer stacked units U.

In some embodiments, the operation of forming the multilayer stacked units U on the substrate 2 from the operation S100 may be specifically understood as follows: including the following operations S110 and S120.

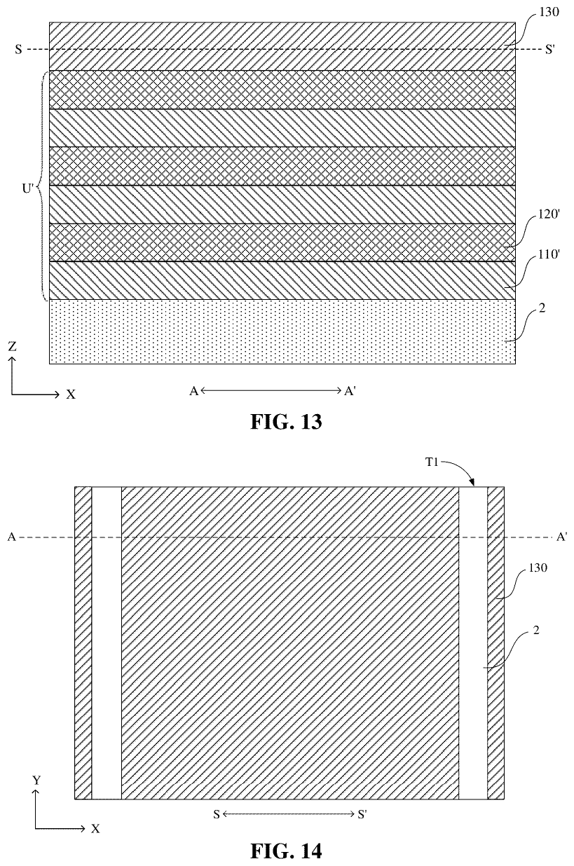

In operation S110, as shown in FIG. 12 and FIG. 13, sacrificial material layers 110′ and interlayer dielectric material layers 120′ covering the entire substrate are sequentially and alternately stacked along the first direction (such as the Z direction), to form a stacked structure U′ before patterning. It should be noted that FIG. 12 is a schematic cross-sectional structural diagram of the structure shown in FIG. 13 in an SS′ direction.

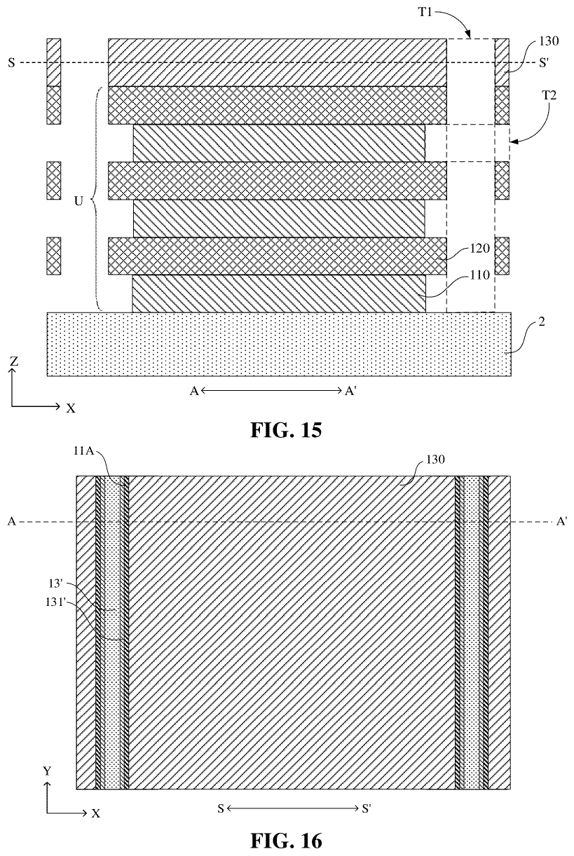

In operation S120, as shown in FIG. 14 and FIG. 15, the stacked structure U′ is etched along the first direction (such as the Z direction), to form multiple first trenches T1 extending along the second direction (such as the Y direction) and arranged at intervals in the X direction and penetrating to the substrate, and form the multilayer stacked units U located on two sides of each of the first trenches T1 along the third direction (such as the X direction). It should be noted that FIG. 14 is a schematic cross-sectional structural diagram of the structure shown in FIG. 15 in an SS′ direction. FIG. 14 and FIG. 15 show three multilayer stacked units U schematically, a middle one of the three multilayer stacked units is a complete multilayer stacked unit U, and another two of the three multilayer stacked units are only intended to reflect formation of trenches before the complete multilayer stacked unit U, and do not reflect the complete multilayer stacked unit U.

It should be noted that in the embodiments of the disclosure, interlayer dielectric layers 120 in the multilayer stacked units U may be used as the third isolation structures 5 in the foregoing embodiments.

In the embodiments of the disclosure, a number of layers of sacrificial layers 110 may be set according to a required number of layers of memory cells of the memory stacked in the first direction (such as the Z direction), and a layer of memory cells may be formed in each sacrificial layer 110. Exemplary descriptions will be made below by an example that top of each of the multilayer stacked units U is the interlayer dielectric layer 120 and bottom of each of the multilayer stacked units U is the sacrificial layer 110. A layer of memory cells contains at least one transistor, and in some embodiments, may also contain capacitors.

As an example, the sacrificial layer 110 may be made of a polycrystalline silicon (poly-Si) material or an amorphous silicon (a-Si) material. As an example, the interlayer dielectric layer 120 may be made of silicon oxide or similar materials.

In the operation S200, as shown in FIG. 14 and FIG. 15, sacrificial layers 110 exposed by a sidewall of each of the first trenches T1 are back etched, which may be understood as laterally etching regions of sidewalls of the sacrificial layers 110 located in the second direction (such as the Y direction) to form multiple first accommodation grooves T2 each of which is located between any two adjacent interlayer dielectric layers, each of the first accommodation grooves T2 is opened towards the first trench T1, and all the grooves extend along the column direction.

As shown in FIG. 16 to FIG. 19, the initial semiconductor layer, the gate dielectric layer 131 and the WL 13 are sequentially formed on the inner wall of each of the first accommodation grooves T2. The initial semiconductor layers in the first accommodation grooves T2 are not spaced apart, rather than continuously provided; however, the initial semiconductor layer in each of the first accommodation grooves T2 is continuously distributed in each area of the accommodation groove.

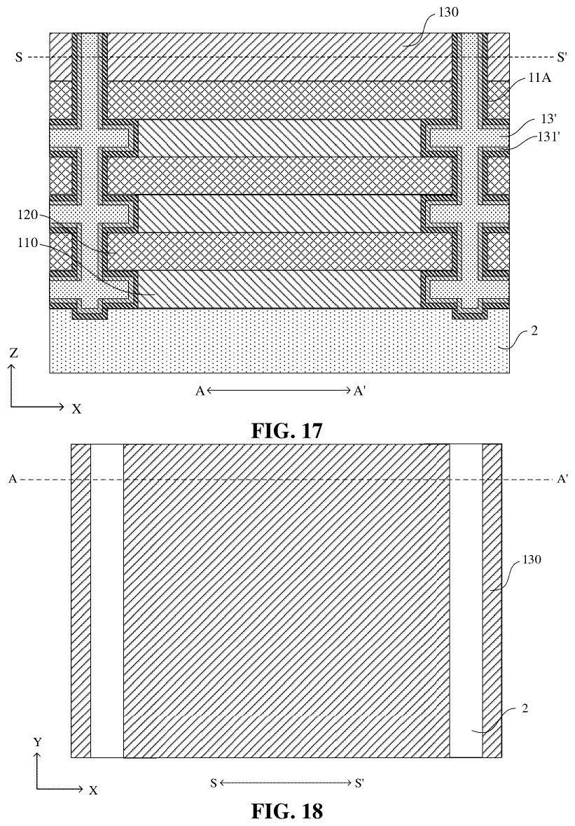

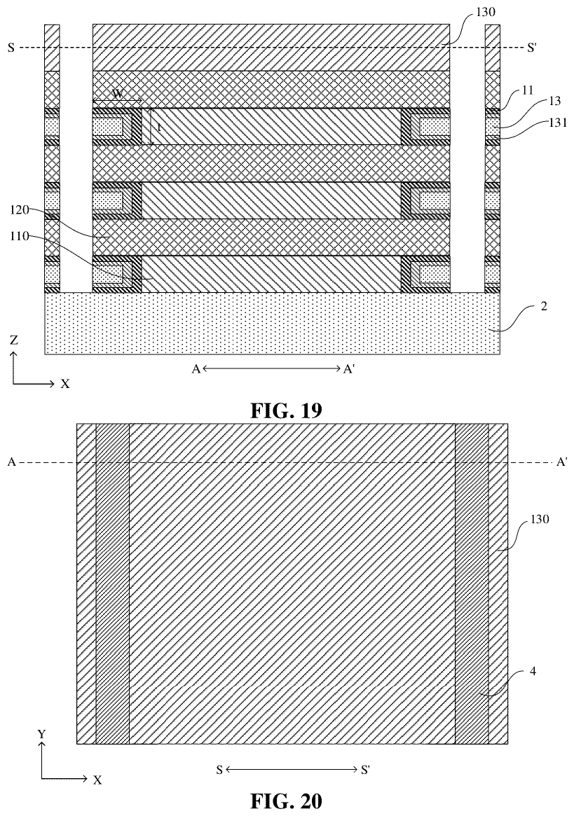

It should be noted that FIG. 16 is a schematic cross-sectional structural diagram of the structure shown in FIG. 17 in an SS′ direction, and FIG. 18 is a schematic cross-sectional structural diagram of the structure shown in FIG. 19 in an SS′ direction.

In some embodiments, as shown in FIG. 16 to FIG. 19, the operation of sequentially forming the initial semiconductor layer, the gate dielectric layer 131 and the WL 13 on the inner wall of the first accommodation groove T2 from the operation S200 may be specifically reflected as the following operations for example.

As shown in FIG. 16 and FIG. 17, semiconductor material layers 11A, gate dielectric material layers 131′ and WL material layers 13′ are sequentially formed on the first trenches T1 and the inner walls of the first accommodation grooves T2 that have two ends communicating with each other. Thereafter, the semiconductor material layer 11A, the gate dielectric material layer 131′ and the WL material layer 13′ in each of the first trenches T1 are removed, such that the semiconductor material layer 11A retained in each first accommodation groove T2 is broken, and each semiconductor material layer 11A constitutes the initial semiconductor layer. As shown in FIG. 18 and FIG. 19, the gate dielectric material layer 131′ retained in each first accommodation groove T2 constitutes the gate dielectric layer 131 independent of each other, and the WL material layer 13′ retained in each first accommodation groove T2 constitutes the WL 13 independent of each other in the direction perpendicular to the substrate.

In the operation S300, it needs to break the semiconductor layer surrounding the same WL to eliminate a parasitic Metal Oxide Semiconductor (MOS). Specifically, a groove is dug on the stacked structure in the direction perpendicular to the substrate, the groove penetrates each of the stacked layers, extends along the row direction, and is perpendicular to the first trench T1 as a whole. A memory cell is arranged between two adjacent trenches of a WL extending along the X direction, the trenches extending along the X direction break the sacrificial layer 110, the interlayer dielectric layer 120 and the initial semiconductor layer, and back of each initial semiconductor layer surrounding the same WL is broken to form a semiconductor layer corresponding to each transistor. The trenches do not disconnect the WL or disconnect the WL from the gate insulation layer. Dielectric layers are filled in the trenches to form the first isolation structures 3 described below.

The above contents may also be understood as multiple areas extending along the X direction and spaced apart in the Y direction, here the sacrificial layers 110, the interlayer dielectric layers 120 and the initial semiconductor layers are etched in each of the areas along the first direction (such as the Z direction), to separate the initial semiconductor layer into multiple semiconductor layers 11 arranged at intervals in the second direction (such as the Y-direction).

Each of the semiconductor layers 11 is provided with two opposite main surfaces, the two opposite main surfaces are a first side away from the WL 13 and a second side facing towards the WL 13 respectively. Each of the semiconductor layers 11 may include, on the first side, a source contact region and a drain contact region spaced apart from each other, and a channel region between the source contact region and the drain contact region. As shown in FIG. 19, a size of the channel region in each of the semiconductor layers 11 in the third direction (such as the X direction) is W, and a size of the channel region in each of the semiconductor layers 11 in the first direction (such as the Z direction) is t. It may be understood that a size of the channel region in each of the semiconductor layers 11 is 2*W+t.

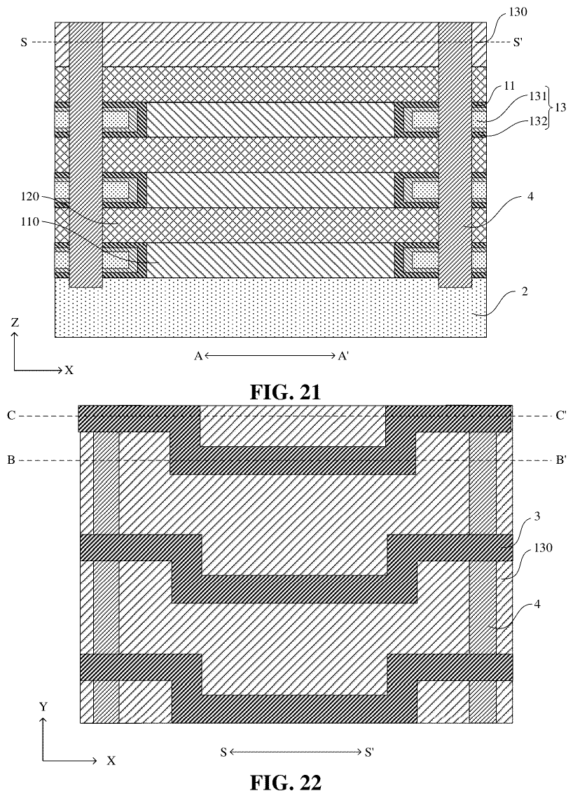

In some embodiments, as shown in FIG. 20 and FIG. 21, the method for preparing the memory may further include the following operation after the operation S300. A second isolation structure 4 is filled in each of the first trenches T1. It should be noted that FIG. 20 is a schematic cross-sectional structural diagram of the structure shown in FIG. 21 in an SS′ direction.

As an example, a top surface of the second isolation structure 4 may be flushed with a top surface of a hard mask layer 130 by using a planarization process, which is beneficial to reduce a defect density, thereby improving production yield and usage reliability of the memory. Exemplarily, the planarization process may include a Chemical-Mechanical Polishing (CMP) process.

With reference to FIG. 20 to FIG, 24, in some embodiments, the method for preparing the memory may further include the following operations after the operation S300. A first isolation structure 3 is formed in an etched area of each of the sacrificial layer 110, the interlayer dielectric layer 120 and the initial semiconductor layer 11, that is, in a trench for breaking the semiconductor layer in different areas on a WL. It should be noted that FIG. 22 is a schematic cross-sectional structural diagram of the structure shown in FIG. 24 in an SS′ direction. The first isolation structure 3 is an insulation layer filling the trench, the first isolation structure has a shape adapted to that of the trench. Multiple trenches extend along the X direction. The first isolation structure 3 consists of multiple insulation layers, the insulation layers extend along the direction perpendicular to the substrate while extend along the X direction; however, cross sections of the insulation layers do not necessarily have a shape of straight lines and may be partially curved.

The first isolation structure 3 is located between semiconductor layers 11 adjacent to each other in the second direction (such as the Y direction) from the multiple semiconductor layers, extends along the third direction (such as the X direction), and is provided with a bending portion bent along the second direction (such as the Y direction).

In the method for preparing the memory provided in the above embodiments, the semiconductor layer of the transistor is located between two adjacent first isolation structures 3, and naturally, all of the source contact region, the drain contact region, the channel region and the BL of the transistor are located between two adjacent first isolation structures 3. In a 1T1C structure, in order to prepare a capacitor between two adjacent first isolation structures 3, profiles of electrodes of the capacitor are determined by etching the sacrificial layer. Therefore, it needs to form a via penetrating layers in an area between two adjacent first isolation structures 3, and form an insulation structure 15 in the via, the insulation structure 15 is an etching barrier layer. A cavity profile of the first electrode of the capacitor is determined by etching the sacrificial layer and stopping at the etching barrier layer.

As an example, the BL 12 is located in an area surrounded by the drain contact region, the first isolation structure 3 and the insulation structure 15.

As an example, a top surface of the first isolation structure 3 may be flushed with the top surface of the hard mask layer 130 by using a planarization process, which is beneficial to reduce a defect density, thereby improving production yield and usage reliability of the memory. Exemplarily, the planarization process may include a CMP process.

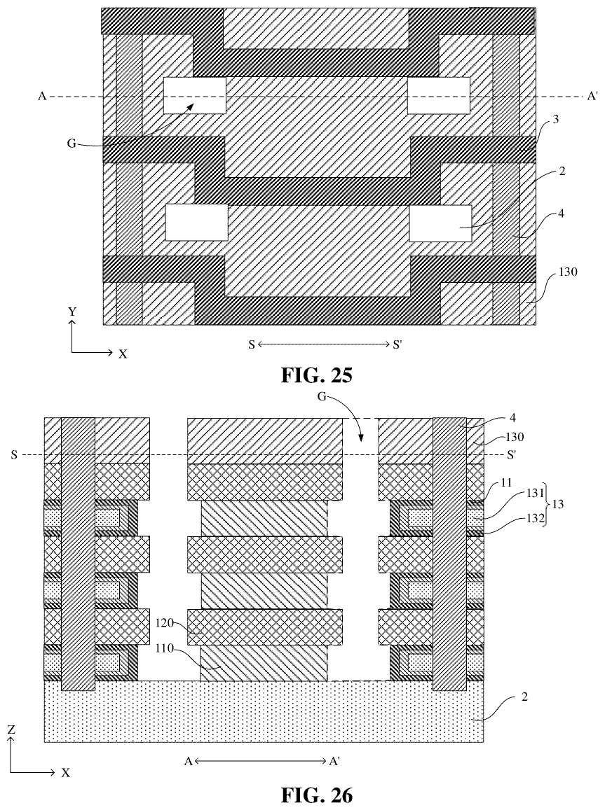

With reference to FIG. 25 and FIG, 26, the method for preparing the memory may further include the following operations before the operation S400.

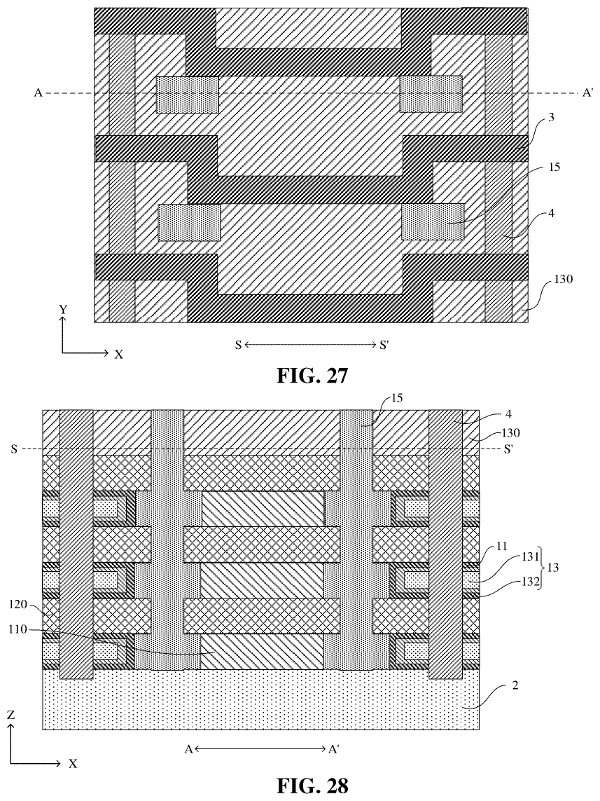

As shown in FIG. 25 and FIG. 26, a spacing hole G, which penetrates the multilayer stacked unit U in the first direction (such as the Z direction) and exposes the channel region of each corresponding layer, is formed in a third area of the multilayer stacked unit U. Thereafter, as shown in FIG. 27 and FIG. 28, a dielectric layer is filled in the spacing hole G, to form an insulation structure 15. Materials of the insulation structure and the sacrificial layer have an etching selectivity ratio. It should be noted that FIG. 25 is a schematic cross-sectional structural diagram of the structure shown in FIG. 26 in an SS′ direction, and FIG. 27 is a schematic cross-sectional structural diagram of the structure shown in FIG. 28 in an SS′ direction.

In the method provided in the above embodiments, second accommodation grooves T5 are formed by the operation S700 and the operation S800, and each of the second accommodation grooves T5 includes multiple layers spaced apart by the interlayer dielectric layer, and a second accommodation groove is formed between any two adjacent first isolation structures 3 in each layer.

The second accommodation groove T5 is obtained by laterally etching each sacrificial layer, and an isolation groove is provided in a middle region in a column direction of each of the multilayer stacked units U, to expose ends of the sacrificial layer and the interlayer dielectric layer. The sacrificial layer is back etched, the sacrificial layer is etched to an extent of exposing two adjacent first isolation structures 3, the insulation structure 15 and the source contact region of the semiconductor, and a cavity thus formed is used to form the capacitor. Specifically, the first electrode, the dielectric layer and the second electrode of the capacitor may be formed by using an ALD method.

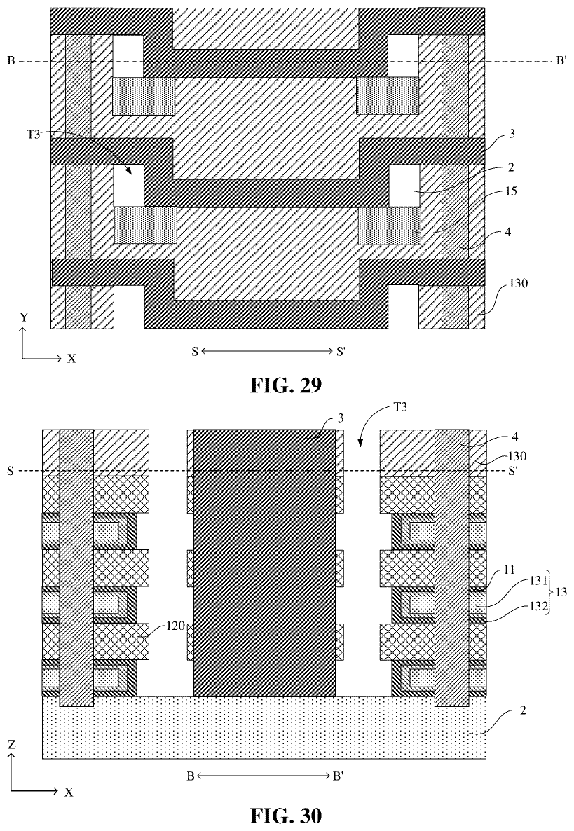

In the operation S400, as shown in FIG. 29 to FIG. 30, a BL hole T3, which penetrates the multilayer stacked unit in the first direction (such as the Z direction) and exposes the drain contact region of each corresponding layer, is formed in a first area of the multilayer stacked unit U. It should be noted that FIG. 29 is a schematic cross-sectional structural diagram of the structure shown in FIG. 30 in an SS′ direction.

In some embodiments, the third area may define the spacing between the BL hole 13 and the second accommodation groove T5.

As an example, the third area may be adjacent to the first area, and a size of the third area in the third direction (such as the X direction) may be greater than that of the first area in the third direction (such as the X direction).

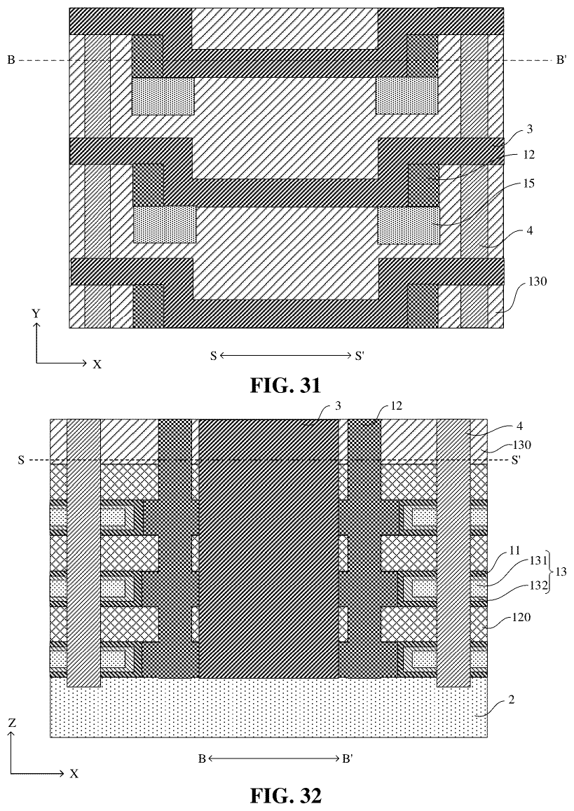

With reference to FIG. 31 and FIG. 32, in the operation S500, a BL 12 is formed in the BL hole T3. It should be noted that FIG. 31 is a schematic cross-sectional structural diagram of the structure shown in FIG. 32 in an SS′ direction.

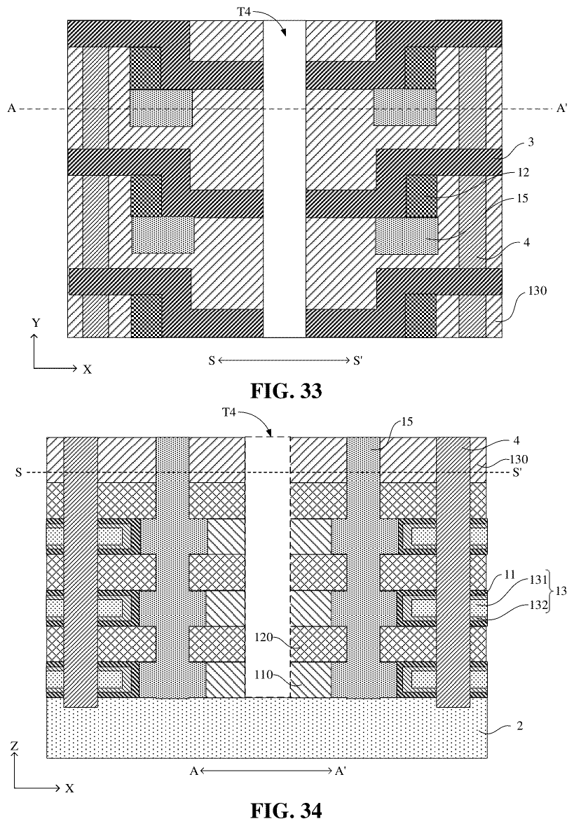

With reference to FIG. 33 and FIG. 34, in the operation S600, an etching groove T4 which penetrates the multilayer stacked unit U in the first direction (such as the Z direction) and extends along the second direction (such as the Y direction), is formed in a second area of each of the multilayer stacked units U.

It should be noted that FIG. 33 is a schematic cross-sectional structural diagram of the structure shown in FIG. 34 in an SS′ direction, each second area has a spacing from the first area in the third direction (such as the X direction).

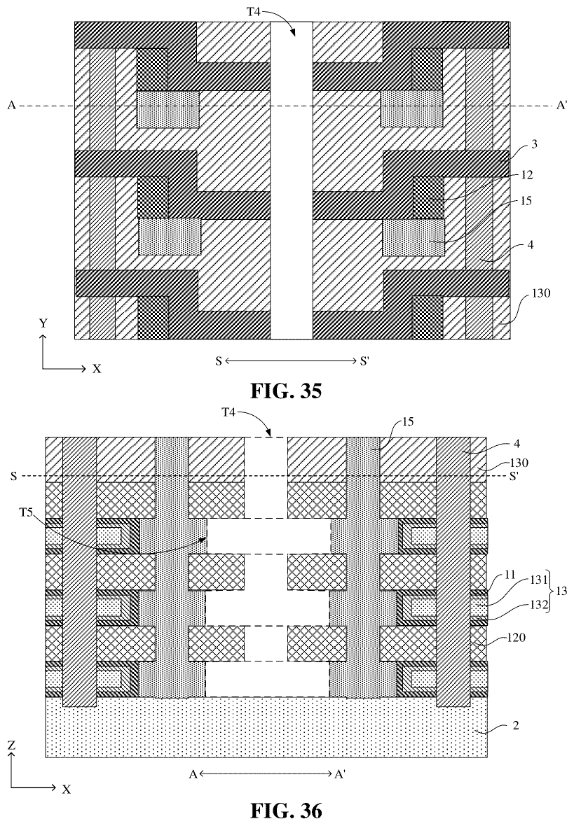

It should be noted that FIG. 35 is a schematic cross-sectional structural diagram of the structure shown in FIG. 36 in an SS′ direction, the second accommodation groove T5 has a spacing from the BL hole T3 in each of the second direction (such as the Y direction) and the third direction (such as the X direction).

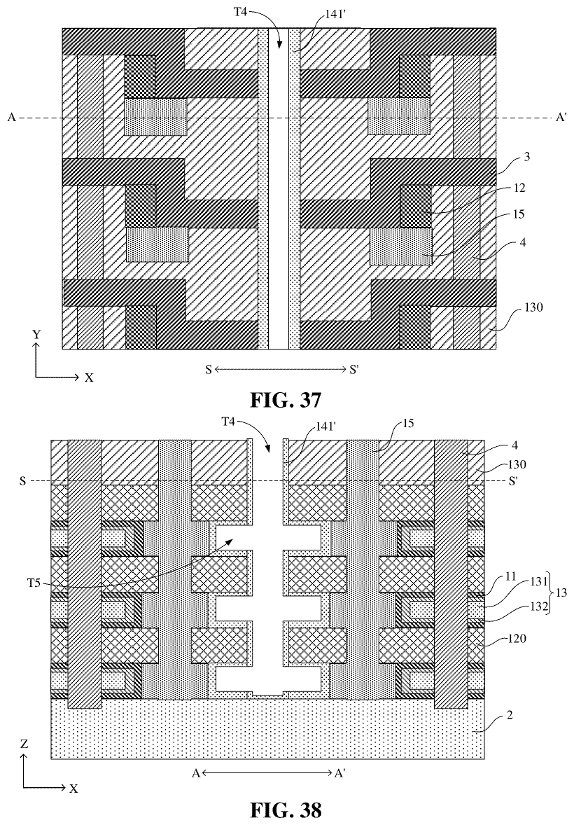

With reference to FIG. 37 to FIG. 40, in the operation S800, a capacitor 14 is formed in the second accommodation groove T5.

In some embodiments, the operation S800 may be specifically reflected as the following operations.

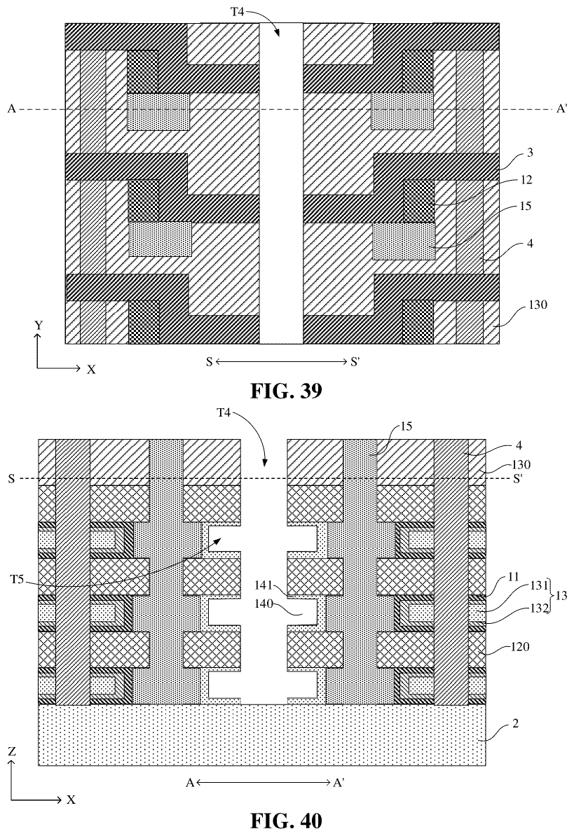

As shown in FIG. 37 and FIG. 38, a first electrode material layer 141′ is conformally covered and formed on sidewalls of each of the second accommodation grooves T5 and each of etching grooves T4. As shown in FIG. 39 and FIG. 40, the first electrode material layer 141′ formed on the sidewall of each of the etching grooves T4 is removed, and the first electrode material layer 141′ conformally covered on the sidewall of each of the second accommodation grooves T5 is retained as the first electrode 141. Thereafter, a dielectric layer 143 is conformally covered on the sidewall of each of the second accommodation grooves T5 and an inner wall of the first electrode 141, and the second electrode 142 is solidly filled in each of the second accommodation grooves T5 and each of the etching grooves T4. The first electrode 141, the second electrode 142 and the dielectric layer 143 between the first electrode 141 and the second electrode 142 constitute the capacitor 14 together, and the obtained capacitor 14 may refer to FIG. 1, FIG. 2, FIG. 4, FIG. 5 and FIG. 9.

It should be noted that FIG. 37 is a schematic cross-sectional structural diagram of the structure shown in FIG. 38 in an SS′ direction, and FIG. 39 is a schematic cross-sectional structural diagram of the structure shown in FIG. 40 in an SS′ direction.

As an example, the first electrode material layer 141′ may be conformally covered on sidewalls of each of the second accommodation grooves T5 and each of the etching grooves T4 by using an ALD process, without limiting to only the ALD process.

According to some embodiments, the disclosure further provides an electronic device, such as a data storage device, a photocopier, a network device, a household appliance, an instrument and a meter, a mobile phone, a computer, or other devices with a data storage function.

The electronic device may include the semiconductor device provided in any one of the foregoing embodiments, or may include the memory provided in any one of the foregoing embodiments. It may be understood that structures of the semiconductor device and the memory may refer to relevant descriptions in some of the above embodiments. Furthermore, the electronic device may further include other essential elements or components, which are not specifically limited in the disclosure.

The electronic device provided in the above embodiments includes the semiconductor device provided in the foregoing embodiments or the memory provided in the foregoing embodiments. Therefore, technical effects that may be achieved by the semiconductor device provided in the foregoing embodiments or the memory provided in the foregoing embodiments may also be achieved by the above electronic device, which will not be elaborated here. The semiconductor device provided in the foregoing embodiments or the memory provided in the foregoing embodiments may not only achieve 3D storage to improve the storage density, but also have higher read, write and refresh speed, and thus have better performance and usage reliability.

It should be noted that the above embodiments are only for the purpose of descriptions, and are not meant to limit the disclosure.

Various embodiments in the description are described in a progressive manner, each embodiment focuses on describing differences from other embodiments, the same or similar parts between various embodiments may refer to each other.

Various technical features of the above embodiments may be combined arbitrarily. In order to make descriptions concise, all possible combinations of various technical features in the above embodiments are not described. However, combinations of these technical features should be considered as falling within the scope of the description, as long as the combinations do not conflict there-between.

The above embodiments only express several implementations of the disclosure, and they are described relatively specifically and in detail; however, they cannot be understood as limiting the patent scope of the disclosure. It should be pointed out that several modifications and improvements may also be made by those of ordinary skill in the art without departing from the concept of the disclosure, and all of them fall within the scope of protection of the disclosure. Therefore, the patent scope of protection of the disclosure shall be subject to the appended claims.

1. A semiconductor device, arranged on a substrate, comprising:
semiconductor layers, each of which is provided with two opposite main surfaces, the two opposite main surfaces being a first side and a second side of each of the semiconductor layers respectively, and each of which comprises, on the first side, a source contact region and a drain contact region spaced apart from each other, and a channel region between the source contact region and the drain contact region;
bit lines (BLs), each of which is arranged on the first side of a respective one of the semiconductor layers, is connected to the drain contact region, and extends along a first direction perpendicular to a surface of the substrate; and
word lines (WLs), each of which is arranged on the second side of a respective one of the semiconductor layers, and extends along a second direction parallel to the surface of the substrate.

2. The semiconductor device of claim 1, further comprising: capacitors, each of which is arranged on the first side of a respective one of the semiconductor layers and is connected to the source contact region.

3. The semiconductor device of claim 1, wherein each of the semiconductor layers surrounds a sidewall of a respective one of the WLs and is insulated from the respective one of the WLs, the first side of each of the semiconductor layers comprises an upper surface, a lower surface and a side surface, and the source contact region, the drain contact region and the channel region are located at least on the side surface.

4. The semiconductor device of claim 2, wherein each of the capacitors comprises a first electrode, a second electrode and a dielectric layer between the first electrode and the second electrode,
wherein the first electrode is connected to the source contact region and is provided with a cup-shaped cavity, the second electrode is solidly filled in the cup-shaped cavity of the first electrode.

5. The semiconductor device of claim 4, wherein each of the BLs is in contact with the source contact region, and the first electrode is in contact with the drain contact region.

6. The semiconductor device of claim 4, further comprising:
insulation structures, each of which is located between a respective one of the BLs and the first electrode, and separates the respective one of the BLs, the channel region and the first electrode from each other.

7. The semiconductor device claim 4, wherein an orthographic projection of each of the BLs on a 2 Dimension (2D) plane formed by the first direction and the second direction is not overlapped with an orthographic projection of the first electrode on the 2D plane.

8. A memory, comprising:
a substrate;
a memory cell array, comprising a plurality of layers of memory cells stacked in a first direction, wherein memory cells located in a same layer among the plurality of layers of memory cells are arranged in columns in a second direction and arranged in rows in a third direction, the first direction is perpendicular to a surface of the substrate, the second direction is parallel to the surface of the substrate, and the third direction is parallel to the surface of the substrate and intersects with the second direction; each of the memory cells comprises transistors, the transistor comprises a semiconductor layer, the semiconductor layer is provided with two opposite main surfaces, the two opposite main surfaces are a first side and a second side of the semiconductor layer respectively, and the semiconductor layer comprises, on the first side, a source contact region and a drain contact region spaced apart from each other, and a channel region between the source contact region and the drain contact region;
a plurality of bit lines (BLs), wherein a same BL extending along the first direction is shared by all layers of memory cells located at a same position of the memory cell array, and each of the plurality of BLs is arranged on the first side of a corresponding one of the semiconductor layers and is connected to the drain contact region of the corresponding one of the semiconductor layers; and
a plurality of word lines (WLs), wherein a same WL extending along the second direction is shared by memory cells located in a same column among the memory cells located in the same layer, and each of the plurality of WLs is arranged on the second side of a respective one of the semiconductor layers.

9. The memory of claim 8, wherein each of the memory cells further comprises:
capacitors, each of which is arranged on the first side of a respective one of the semiconductor layers and is connected to the source contact region.

10. The memory of claim wherein each of the capacitors comprises a first electrode, a second electrode and a dielectric layer between the first electrode and the second electrode, the first electrode is provided with a cup-shaped cavity, the second electrode is solidly filled in the cup-shaped cavity of the first electrode,
wherein an end of the second electrode extends along the first direction and the second direction,
second electrodes of all layers of memory cells located at the same position of the memory cell array are connected integrally, and second electrodes of the memory cells located in the same column among the memory cells located in the same layer are connected integrally.

11. The memory of claim 10, wherein in two memory cells adjacent to each other in the second direction among the memory cells located in the same layer, an orthographic projection of the BL corresponding to one of the two memory cells on a plane where the first direction intersects with the second direction is partially overlapped with an orthographic projection of the first electrode of another one of the two memory cells on the plane.

12. The memory of claim 10, wherein two memory cells adjacent to each other in the third direction among the memory cells located in the same layer form a memory group, second electrodes of two memory cells from a same memory group are interconnected, and the two memory cells are symmetrically arranged with respect to a symmetry center of an interconnected structure of the second electrodes,
the memory further comprises a plurality of first isolation structures and a plurality of second isolation structures,
each of the first isolation structures is located between two memory groups adjacent to each other in the second direction, and covers at least sidewalls of a corresponding one of the semiconductor layers, a corresponding one of the BLs and the first electrode of a corresponding one of the capacitors in the third direction,
each of the second isolation structures is located between two memory groups adjacent to each other in the third direction, covers at least sidewalls of a corresponding one of the WLs and a corresponding one of the semiconductor layers in the second direction, and is correspondingly connected to a respective one of the first isolation structures.

13. The memory of claim 12, further comprising: a plurality of third isolation structures, located between different layers of memory groups adjacent to each other in the first direction,
wherein each of the first isolation structures and each of the second isolation structures extend along the first direction, and are connected to a respective one of the third isolation structures.

14. A method for preparing a memory, comprising:
providing a substrate, and forming multilayer stacked units on the substrate, wherein each of the multilayer stacked units comprises sacrificial layers and interlayer dielectric layers sequentially and alternately stacked along a first direction perpendicular to a surface of the substrate;
back etching a sidewall of each sacrificial layer in a second direction, to form a first accommodation groove, and sequentially forming an initial semiconductor layer, a gate dielectric layer and a word line (WL) on an inner wall of the first accommodation groove, wherein the second direction is parallel to the surface of the substrate;
etching the sacrificial layers, the interlayer dielectric layers and the initial semiconductor layers along the first direction, to separate the initial semiconductor layer into a plurality of semiconductor layers arranged at intervals in the second direction, wherein each of the semiconductor layers is provided with two opposite main surfaces, the two opposite main surfaces are a first side away from the WL and a second side facing towards the WL respectively, and each of the semiconductor layers comprises, on the first side, a source contact region and a drain contact region spaced apart from each other, and a channel region located the source contact region and the drain contact region;
forming, in a first area of the multilayer stacked unit, a bit line (BL) hole which penetrates the multilayer stacked unit in the first direction and exposes the drain contact region of each corresponding layer;
forming a BL in the BL hole;
forming, in a second area of each of the multilayer stacked units, an etching groove which penetrates the multilayer stacked unit in the first direction and extends along the second direction, wherein each second area has a spacing from the first area in a third direction, and the second direction and the third direction are parallel to the surface of the substrate and intersect with each other;
etching the sacrificial layer, to form a second accommodation groove and expose the source contact region of a corresponding layer, wherein the second accommodation groove has a spacing from the BL hole in each of the second direction and the third direction; and
forming a capacitor in the second accommodation groove.

15. The method for preparing the memory of claim 14, further comprising:
before forming, in the first area of the multilayer stacked unit, the BL hole which penetrates the multilayer stacked unit in the first direction and exposes the drain contact region of each corresponding layer,
forming, in a third area of the multilayer stacked unit, a spacing hole which penetrates the multilayer stacked unit in the first direction and exposes the channel region of each corresponding layer, wherein the third area defines the spacing between the BL hole and the second accommodation groove; and
forming an insulation structure in the spacing hole,
wherein the second accommodation groove further exposes a sidewall of the insulation structure away from the channel region.

16. The method for preparing the memory of claim 15, further comprising: after etching the sacrificial layers, the interlayer dielectric layers and the initial semiconductor layers along the first direction, to separate the initial semiconductor layer into the plurality of semiconductor layers arranged at intervals in the second direction,
forming a first isolation structure in an etched area of each of the sacrificial layer, the interlayer dielectric layer and the initial semiconductor layer, wherein the first isolation structure is located between semiconductor layers adjacent to each other in the second direction among the plurality of semiconductor layers, extends along the third direction, and is provided with a bending portion bent along the second direction,
wherein the BL is located in an area surrounded by the drain contact region, the first isolation structure and the insulation structure.

17. The method for preparing the memory of claim 14, wherein forming the multilayer stacked units on the substrate comprises:
sequentially and alternately stacking the sacrificial material layers and the interlayer dielectric material layers along the first direction, to form a stacked structure; and
etching the stacked structure along the first direction, to form a plurality of first trenches extending along the second direction and arranged at intervals, and form the multilayer stacked units located on two sides of each of the first trenches along the third direction, wherein sequentially forming the initial semiconductor layer, the gate dielectric layer and the WL on the inner wall of the first accommodation groove further comprises:
sequentially forming semiconductor material layers, gate dielectric material layers and WL material layers on the first trenches and the inner walls of the first accommodation grooves that have two ends communicating with each other; and removing the semiconductor material layer, the gate dielectric material layer and the WL material layer in each of the first trenches, such that the semiconductor material layer retained in the first accommodation groove constitutes the initial semiconductor layer, the gate dielectric material layer retained in the first accommodation groove constitutes the gate dielectric layer, and the WL material layer retained in the first accommodation groove constitutes the WL,
the method further comprises: forming a second isolation structure in each of the first trenches.

18. (canceled)
